(19) United States
(12) Patent Application Publication
(10) Pub. No.: US 2025/0066898 A1
(43) Pub. Date: Feb. 27, 2025

(54) MASK ASSEMBLY, METHOD OF MANUFACTURING THE MASK ASSEMBLY, AND APPARATUS FOR MANUFACTURING DISPLAY APPARATUS

(71) Applicant: Samsung Display Co., LTD., Yongin-si (KR)

(72) Inventors: Mina WOO, Yongin-si (KR); Jongdae LEE, Yongin-si (KR); Jongbum KIM, Yongin-si (KR); Jongsung PARK, Yongin-si (KR)

(21) Appl. No.: 18/746,778

(22) Filed: Jun. 18, 2024

(30) Foreign Application Priority Data
Aug. 23, 2023 (KR) 10-2023-0110765

(51) Int. Cl. C23C 14/04

(52) U.S. Cl. CPC C23C 14/042

(57) ABSTRACT

A mask assembly includes a mask frame including a plurality of ribs including a first rib extending in a first direction, the plurality of ribs defining an opening area, and a mask sheet disposed on a first surface of the first rib and covering the opening area, where the mask frame further includes a plurality of receiving portions disposed on a second surface of the first rib, and spaced apart from each other in a longitudinal direction of the first rib, the second surface being opposite to the first surface.

This application claims priority to Korean Patent Application No. 10-2023-0110765, filed on Aug. 23, 2023, and all the benefits accruing therefrom under 35 U.S.C. § 119, the content of which in its entirety is herein incorporated by reference.

### BACKGROUND

### 1. Field

Embodiments relate to a mask assembly, a method of manufacturing the mask assembly, and an apparatus for manufacturing a display apparatus, and more particularly, to a mask assembly with an improved arrangement precision, a method of manufacturing the mask assembly, and an apparatus for manufacturing a display apparatus.

### 2. Description of the Related Art

Electronic devices are being widely used. Electronic devices are being variously used in mobile electronic devices and stationary electronic devices. Electronic devices include display apparatuses that may provide users with visual information, such as images or videos, to support various functions.

A display apparatus that visually displays data is formed by depositing various layers, such as an organic layer, a metal layer, and the like. A deposition material may be deposited to form a plurality of layers of the display apparatus. In other words, the deposition material may be ejected from a deposition source and deposited on a substrate through a mask assembly. In this case, the mask assembly includes a mask frame and a mask sheet and may be manufactured while being seated on a mask stage. When the mask sheet is fixed to the mask frame, it is important to position the mask sheet on the mask frame as designed. To this end, immediately after the mask sheet is welded to the mask frame, gas may be sprayed from the mask stage to lift the mask frame and reduce friction between the mask stage and the mask frame.

### SUMMARY

Embodiments include a mask assembly in which a mask sheet is accurately disposed in a mask frame, a method of manufacturing the mask assembly, and an apparatus for manufacturing a display apparatus.

Embodiments set forth herein are illustrative, and the scope of the disclosure is not limited thereby.

Additional features will be set forth in part in the description which follows and, in part, will be apparent from the description, or may be learned by practice of the presented embodiments of the disclosure.

In an embodiment of the disclosure, a mask assembly includes a mask frame including a plurality of ribs including a first rib extending in a first direction,, the plurality of ribs defining an opening area defined, and a plurality of receiving portions disposed on a first surface of the first rib and spaced apart from each other in a longitudinal direction of the first rib and a mask sheet disposed on a second surface of the first rib of the mask frame and covering the opening area, the second surface being opposite to the first surface.

In an embodiment, the plurality of receiving portions may be provided in an odd number.

In an embodiment, each of the plurality of receiving portions may have a constant width in the longitudinal direction.

In an embodiment, the plurality of receiving portions may include a first receiving portion disposed at a center of the first rib and a second receiving portion disposed at at least one of opposite ends of the first receiving portion in the longitudinal direction, and where a width of the first receiving portion may be greater than a width of the second receiving portion.

In an embodiment, the plurality of receiving portions may include a first receiving portion disposed at a center of the first rib and a second receiving portion disposed at at least one of opposite ends of the first receiving portion in the longitudinal direction, and where a depth of the first receiving portion may be greater than a depth of the second receiving portion.

In an embodiment, the plurality of ribs may include a second rib extending in a second direction crossing the first direction and having a shorter length than a length of the first rib, and where a depth, among the plurality of receiving portions, of a receiving portion disposed on the second rib may be greater than a depth of a receiving portion, among the plurality of receiving portions, disposed on the first rib.

In an embodiment, a width of the receiving portion disposed on the second rib may be greater than a width of the receiving portion disposed on the first rib.

In an embodiment, a ratio of the sum of lengths of the plurality of receiving portions to a length of the first rib may be about 0.8 to about 0.9.

In an embodiment, a bottom surface of each of the plurality of receiving portions may be concavely formed toward the surface of the first rib on which the mask sheet is disposed.

In an embodiment, a depth of each of the plurality of receiving portions may correspond to about 3% to about 10% of a thickness of the mask frame.

In an embodiment of the disclosure, a method of manufacturing a mask assembly includes disposing, on a mask stage, a mask frame including a first rib extending in a first direction, fixing a mask sheet on the mask frame, and spraying gas into a plurality of receiving portions disposed, on one surface of the first rib facing the mask stage, to be spaced apart from each other in a longitudinal direction of the first rib.

In an embodiment, an odd number of receiving portions may be disposed on the first rib.

In an embodiment, each of the plurality of receiving portions may have a constant width in the longitudinal direction.

In an embodiment, the plurality of receiving portions may include a first receiving portion disposed at a center of the first rib and a second receiving portion disposed at at least one of opposite ends of the first receiving portion in the longitudinal direction, and where a width of the first receiving portion may be greater than a width of the second receiving portion.

In an embodiment, the plurality of receiving portions may include a first receiving portion disposed at a center of the first rib and a second receiving portion disposed at at least one of opposite ends of the first receiving portion in the longitudinal direction, and where a depth of the first receiving portion may be greater than a depth of the second receiving portion.

In an embodiment, the mask frame may further include a second rib extending in a second direction crossing the first direction and having a shorter length than a length of the first rib, and where a depth of a receiving portion, among the plurality of receiving portions, disposed on the second rib may be greater than a depth of a receiving portion, among the plurality of receiving portions, disposed on the first rib.

In an embodiment, a width of the receiving portion disposed on the second rib may be greater than a width of the receiving portion disposed on the first rib.

In an embodiment, a ratio of the sum of lengths of the plurality of receiving portions to a length of the first rib may be about 0.8 to about 0.9.

In an embodiment of the disclosure, an apparatus for manufacturing a display apparatus includes a chamber, a deposition source accommodated in the chamber and facing a display substrate, and a mask assembly disposed between the display substrate and the deposition source, where the mask assembly includes a mask frame including a plurality of ribs including a first rib extending in a first direction, the plurality of ribs defining an opening area, and a plurality of receiving portions disposed on a first surface of the first rib and spaced apart from each other in a longitudinal direction of the first rib, and a mask sheet disposed on a second surface of the first rib of the mask frame and covering the opening area, the second surface being opposite to the first surface.

In an embodiment, the plurality of receiving portions may be provided in an odd number.

Other features and advantages than those described above will become apparent from the following drawings, claims, and detailed descriptions to embody the disclosure below.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic conceptual diagram showing an embodiment of an apparatus and a method for manufacturing a mask assembly;

FIG. 2 is a schematic perspective view showing an embodiment of a mask stage and a mask assembly;

FIG. 3 is a bottom view showing an embodiment of a bottom surface of a mask frame;

FIG. 4 is a diagram showing flatness of a bottom surface of a mask frame according to the number of receiving portions;

FIG. 5 is a diagram showing flatness of a bottom surface of a mask frame according to the length ratio between a first rib and a receiving portion;

FIG. 6 is a bottom view showing an embodiment of a bottom surface of a mask frame;

FIG. 7 is a bottom view showing an embodiment of a bottom surface of a mask frame;

FIG. 8 is a schematic cross-sectional view of an embodiment of an apparatus for manufacturing a display apparatus including a mask frame;

FIG. 9 is a schematic plan view of an embodiment of a display apparatus manufactured by an apparatus for manufacturing a display apparatus; and

FIG. 10 is a schematic cross-sectional view of an embodiment of a display apparatus manufactured by an apparatus for manufacturing a display apparatus, in an embodiment, which may correspond to a cross-section of the display apparatus of FIG. 9 taken along line X-X′ of FIG. 9.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the illustrated embodiments, and particular embodiments will be illustrated in the drawings and described in the detailed description section. The effect and features of the illustrated embodiments, and a method to achieve the same, will be clearer referring to the detailed descriptions below with the drawings. However, the illustrated embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc., may be used herein to describe various components, these components should not be limited by these terms. These terms are only used to distinguish one component from another.

In the following embodiment, the expression of singularity in the specification includes the expression of plurality unless clearly specified otherwise in context.

In the following embodiment, it will be further understood that the terms “includes”, “has”, “including”, and/or “having” used herein specify the presence of stated features or components, but do not preclude the presence or addition of one or more other features or components.

In the following embodiment, it will be understood that when a layer, region, or component is also referred to as being “formed on” another layer, region, or component, it may be directly or indirectly formed on the other layer, region, or component. That is, intervening layers, regions, or components may be present, for example.

Sizes of components in the drawings may be exaggerated for convenience of explanation. In other words, since sizes and thicknesses of components in the drawings are arbitrarily illustrated for convenience of explanation, the following the disclosure is not limited thereto.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an illustrative embodiment may be implemented differently, a predetermined process order may be performed differently from the described order. For example, two consecutively described processes may be performed substantially at the same time or performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

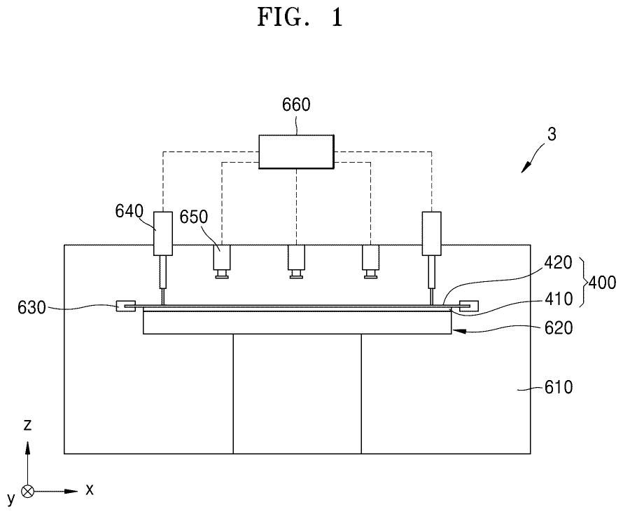

FIG. 1 is a schematic conceptual diagram showing an embodiment of an apparatus and a method for manufacturing a mask assembly.

Referring to FIG. 1, an apparatus 3 for manufacturing a mask assembly may include a chamber 610, a mask stage 620, a clamp 630, a welding portion 640, a vision portion 650, a controller 660, and a gas injector 670.

The chamber 610 may define an internal space therein and may accommodate various components. A mask assembly 400 may be manufactured in the internal space of the chamber 610.

A mask frame 410 is disposed (e.g., seated) on the mask stage 620. The mask stage 620 may form a closed loop to correspond to the shape of the mask frame 410. In an embodiment, the mask stage 620 may have a quadrangular shape with an opening in the center thereof.

The mask stage 620 may include a first side extending in a first direction (e.g., the x direction in FIG. 1). The first side may include or consist of a pair of sides that are arranged to face each other and are parallel to each other. In addition, the mask stage 620 may include a second side extending in a second direction (e.g., the y direction in FIG. 1). The second side may consist of a pair of sides that are arranged to face each other and are parallel to each other. The first side and the second side may intersect each other, e.g., at a right angle. In this case, the profile of the mask stage 620 formed by the first side and the second side may be quadrangular.

In an embodiment, the first side may be a longer side than the second side, and the second side may be a short side. However, the disclosure is not limited thereto, and in another embodiment, the first side may be a short side and the second side may be a long side. In an alternative embodiment, the length of the first side may be equal to the length of the second side. Hereinafter, the description will focus on the case where the first side is the long side and the second side is the short side.

The clamp 630 may clamp the mask sheet 420 seated on the mask frame 410. In an embodiment, the clamp 630 may clamp opposite ends of the mask sheet 420 to tension the mask sheet 420 in a longitudinal direction thereof.

After tensioning as described above, the welding portion 640 may be welded to couple the mask sheet 420 to the mask frame 410. The welding portion 640 may be welded at opposite ends of the mask sheet 420. In this case, in an embodiment, the welding portion 640 may fix the mask sheet 420 to the mask frame 410 by spot welding. Afterwards, opposite ends of the mask sheet 420 clamped by the clamp 630 may be cut.

While the above operation is in progress, the vision portion 650 may detect the positions of the mask sheet 420 and the mask frame 410 and align the position of at least one of the mask sheet 420 and the mask frame 410. In addition, the vision portion 650 may check whether the welding has been accurately performed by photographing a welding position, etc.

The controller 660 may control the operation of each component of the apparatus 3 for manufacturing a mask assembly. In this case, the controller 660 may be provided separately for each component.

The gas injector 670 may be disposed in the mask stage 620. In an embodiment, the gas injector 670 may be disposed below the first and second sides of the mask stage 620. In an alternative embodiment, the gas injector 670 may be integrated into the mask stage 620. The gas injector 670 may spray gas toward the mask frame 410 seated on the mask stage 620 after the mask sheet 420 is welded to the mask frame 410. In an embodiment, the gas injector 670 may include a gas supply unit and an injection hole. The gas supply unit may supply gas to be sprayed toward the mask frame 410. The injection hole may be defined to face the mask frame 410 and may spray gas toward the mask frame 410. In an embodiment, the gas sprayed from the gas injector 670 may be air.

Accordingly, the friction between the mask frame 410 and the mask stage 620 may be reduced. When the mask sheet 420 is welded to the mask frame 410, the mask frame 410 may be deformed due to contraction of the tensioned mask sheet 420. The amount of deformation of the mask frame 410 may be predicted in advance, and the mask sheet 420 may be disposed taking the predicted amount of deformation into consideration. In this case, when the friction between the mask frame 410 and the mask stage 620 is too strong, the deformation of the mask frame 410 may be suppressed and the mask frame 410 may not be deformed to the extent predicted in advance, which may affect the arrangement precision of the mask sheet 420. That is, pattern holes 425 of the mask sheet 420 may not be initially defined in intended positions. The gas injector 670 may spray gas, e.g., air, on the mask frame 410 to provide a lifting force (i.e., flotation force) and reduce the friction between the mask frame 410 and the mask stage 620.

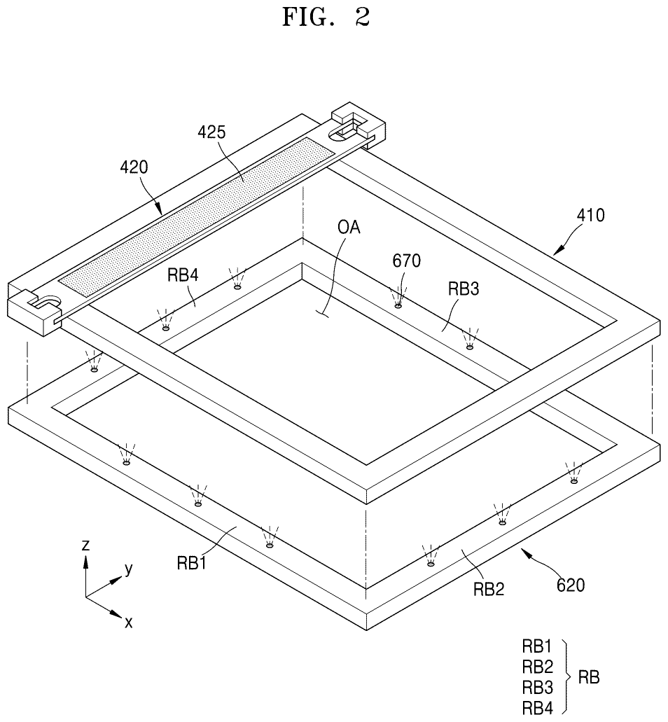

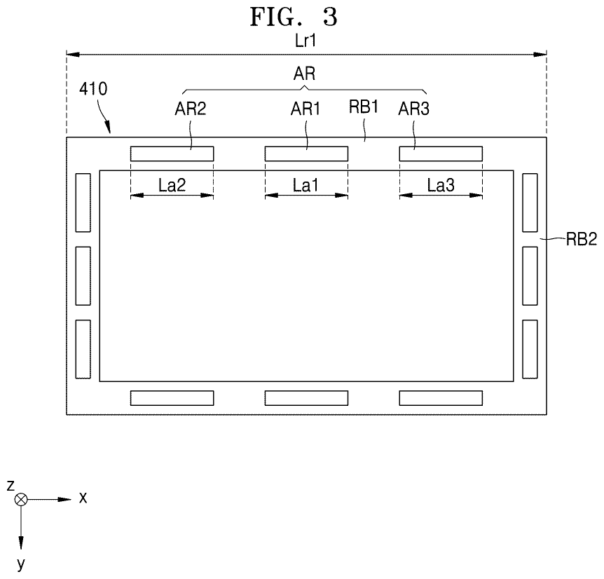

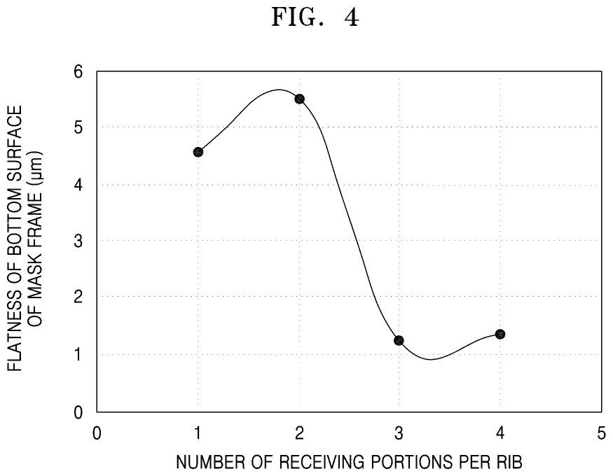

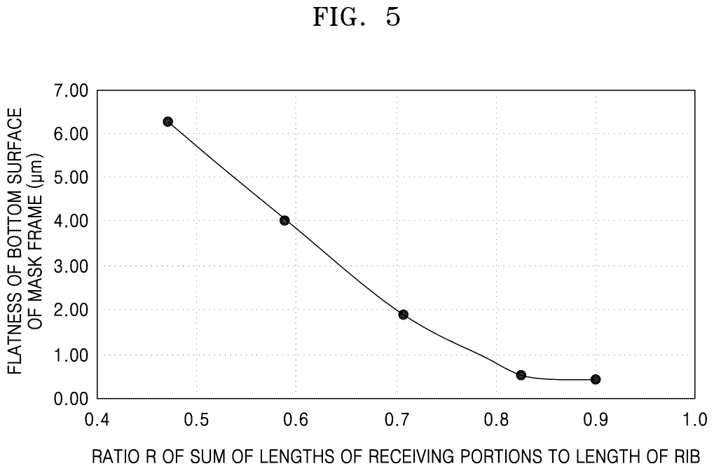

FIG. 2 is a schematic perspective view showing an embodiment of a mask stage and a mask assembly. FIG. 3 is a bottom view showing an embodiment of the bottom surface of a mask frame. FIG. 4 is a diagram showing the flatness of the bottom surface of a mask frame according to the number of receiving portions. FIG. 5 is a diagram showing the flatness of the bottom surface of a mask frame according to the length ratio between a first rib and a receiving portion.

Referring to FIGS. 2 and 3, the mask assembly 400 may be manufactured while seated on the mask stage 620, as described above. The mask assembly 400 may include a mask frame 410 and a mask sheet 420.

The mask frame 410 may be formed by connecting a plurality of ribs RB to each other and may include an opening area OA defined by the plurality of ribs RB. That is, the opening area OA may be formed surrounded by a plurality of ribs RB and may be formed through the center of the mask frame 410.

In an embodiment, the mask frame 410 may be a quadrangular frame. The shape of the mask frame 410 is not limited thereto and may have various polygonal or circular shapes. Hereinafter, for convenience of explanation, the description will focus on the case where the mask frame 410 is a quadrangular frame.

When the mask frame 410 is a quadrangular frame, the plurality of ribs RB may include a first rib RB1 extending in a first direction (e.g., the x direction in FIG. 2) and a second rib RB2 extending in a second direction (e.g., the y direction in FIG. 2) crossing the first direction. In addition, a third rib RB3 disposed to face the first rib RB1 and a fourth rib RB4 disposed to face the second rib RB2 may be further provided, and the first rib RB1 to the fourth rib RB4 may be extended to each other. In an embodiment, the first rib RB1 may correspond to the long side, and the second rib RB2 may correspond to the short side. However, the disclosure is not limited thereto, and the first rib RB1 may correspond to the short side and the second rib RB2 may correspond to the long side, or the length of the first rib RB1 may be equal to the length of the second rib RB2. Hereinafter, for convenience of explanation, the description will focus on the case where the first rib RB1 corresponds to the long side and the second rib RB2 corresponds to the short side.

The mask sheet 420 may be disposed on the first surfaces of the plurality of ribs RB. The mask sheet 420 may be installed in a tensioned state on the mask frame 410. The opening area OA at the center of the mask frame 410 may be covered by the mask sheet 420. In an embodiment, at least one mask sheet 420 may be provided, and when two or more mask sheets 420 are provided, the mask sheets 420 may be disposed on the mask frame 410 to be side by side with each other. In an embodiment, the mask sheets 420 may be arranged side by side in the first direction (e.g., the x direction in FIG. 2), for example. In this case, each of the mask sheets 420 may have a shape extending long in the second direction (e.g., the y direction in FIG. 2). Opposite ends of the mask sheet 420 may be fixed to the mask frame 410 by, e.g., welding. In FIG. 2, only one mask sheet 420 is shown for convenience of explanation.

The mask sheet 420 may define at least one pattern hole 425. The pattern hole 425 may be a through hole defined to allow a deposition material to pass through the mask sheet 420.

The second surfaces of the plurality of ribs RB facing the first surfaces may be seated in contact with the mask stage 620. A plurality of receiving portions AR may be disposed on the second surface of each of the plurality of ribs RB. Hereinafter, for convenience of explanation, the description will focus on the first rib RB1.

A plurality of receiving portions AR spaced apart from each other in a longitudinal direction (e.g., the x direction in FIG. 3) of the first rib RB1 may be disposed on the second surface of the first rib RB1. The receiving portion AR may be a groove defined concavely in a thickness direction (e.g., the z direction in FIG. 3) of the first rib RB1. In an embodiment, the receiving portion AR may have a depth corresponding to 10% or less of the thickness of the first rib RB1, e.g., about 3% to about 10%. When the depth of the receiving portion AR is greater than 10% of the thickness of the first rib RB1, the strength or deformation of the first rib RB1 may be affected. In addition, in an embodiment, the receiving portion AR may have a quadrangular shape, e.g., rectangular shape in a plan view. However, the disclosure is not limited thereto, and the receiving portion AR may have various elongated shapes, such as a tapered quadrangular shape. The receiving portion AR may accommodate gas sprayed from the gas injector 670 and thus provide a lifting force to the ribs RB.

In an embodiment, a plurality of receiving portions AR may be provided. In an embodiment, two or more receiving portions AR may be provided, for example. This may provide uniform flatness to the mask frame 410 compared to the case where a single receiving portion AR is formed along the first rib RB1. In the case where a single receiving portion AR is provided on the rib RB, especially the first rib RB1 corresponding to the long side, when gas is sprayed from the gas injector 670, a portion of the first rib RB1 may be lifted along the longitudinal direction of the first rib RB1 and a load may be concentrated on another portion of the first rib RB1, and thus, it may not be easy to generate uniform flatness. In an embodiment, as a plurality of receiving portions AR is spaced apart from each other in the longitudinal direction of the first rib RB1, each receiving portion AR may accommodate gas uniformly. Therefore, uniform flatness may be provided in the longitudinal direction of the first rib RB1.

Referring to FIG. 4, in an embodiment, an odd number of receiving portions AR may be provided. In an embodiment, the number of receiving portions AR may be three but is not limited thereto and may be five, seven, etc., for example. Hereinafter, for convenience of explanation, the description will focus on the case where the receiving portions AR include a first receiving portion AR1, a second receiving portion AR2, and a third receiving portion AR3.

In FIG. 4, the x-axis represents the number of receiving portions AR disposed on the first rib RB1, and the y-axis represents the flatness (in terms of micrometer (μm)) of the bottom surface of the mask frame 410 in contact with the mask stage 620. In this way, when the receiving portions AR are provided in an odd number rather than in an even number, the lifting force provided to the mask frame 410 may be distributed more uniformly, thereby providing uniform flatness. In addition, because the friction force between the mask frame 410 and the mask stage 620 is uniform over the entirety of the length of the first rib RB1, the mask sheet 420 may be aligned exactly as intended on the mask frame 410.

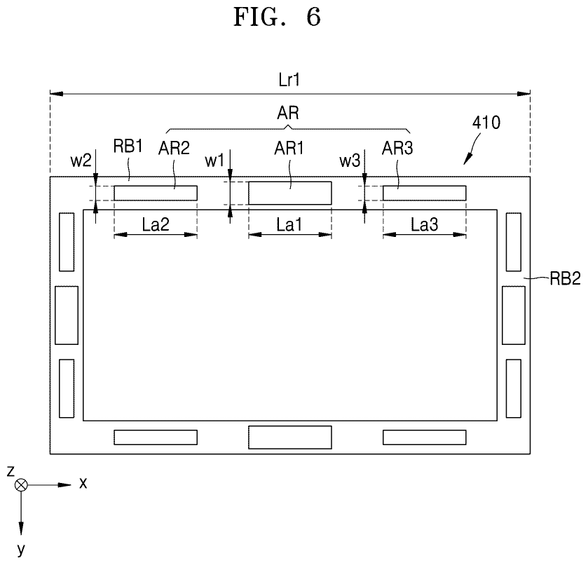

Referring to FIG. 5, in an embodiment, the ratio R of the sum of lengths of the plurality of receiving portions AR to a length Lr1 (refer to FIG. 6) of the first rib RB1 may be about 0.8 to about 0.9. In an embodiment, when three receiving portions AR are provided, the sum of the lengths of the plurality of receiving portions AR may mean the sum of a length La1 of the first receiving portion AR1, a length La2 of the second receiving portion AR2, and a length La3 of the third receiving portion AR3, for example. In addition, the ratio of the sum of the lengths of the plurality of receiving portions AR to the length Lr1 of the first rib RB1 may be defined as (La1+La2+La3)/Lr1. When the ratio R is about 0.8 to about 0.9, the gas may be accommodated in most of the length of the first rib RB1 and a sufficient lifting force may be provided. In addition, because there are a plurality of receiving portions AR, the lifting force provided to the first rib RB1 may be uniformly distributed. Specifically, when the ratio R is 0.8 or less, the flatness of the mask frame 410 may be about 1 μm or more, that is, not sufficiently flat. When the ratio R is 0.9 or more, the effect caused by providing a plurality of receiving portions AR may be reduced.

Referring back to FIG. 3, in an embodiment, each of the plurality of receiving portions AR may have a constant width in the longitudinal direction. In an embodiment, the first receiving portion AR1 may have a predetermined width, for example. In addition, each of the second receiving portion AR2 and the third receiving portion AR3 may also have a predetermined width. In this case, the width of the first receiving portion AR1, the width of the second receiving portion AR2, and the width of the third receiving portion AR3 may be equal to each other. As the receiving portion AR is not formed as a single receiving portion AR but is formed as a plurality of receiving portions AR, the lifting force may be uniformly distributed, and thus, the width of the receiving portion AR may not change in the longitudinal direction.

In addition, in an embodiment, the depths of the plurality of receiving portions AR may be equal to each other. In an embodiment, the depths of the first receiving portion AR1, the second receiving portion AR2, and the third receiving portion AR3 may be equal to each other, for example.

However, in other embodiments, the depths of the plurality of receiving portions AR may be different from each other. In an embodiment, the depth of the first receiving portion AR1 disposed in the center of the first rib RB1 may be greater than the depths of the second receiving portion AR2 and the third receiving portion AR2 respectively arranged at opposite ends of the first receiving portion AR1, for example. In this case, the first receiving portion AR1 may accommodate more gas than the second receiving portion AR2 and the third receiving portion AR3, and the lifting force applied to the first receiving portion AR1 may be greater than the lifting force applied to the second receiving portion AR2 and the third receiving portion AR3. This may compensate for the phenomenon of further lifting occurring at opposite ends of the first rib RB1. That is, the first receiving portion AR1 disposed in the center of the first rib RB1, which is lifted relatively little by gas injection, may accommodate a relatively large amount of gas and increase the lifting force. Accordingly, uniform flatness may be provided throughout the entirety of the length of the first rib RB1. In addition, the above description focuses on the case where there are three receiving portions AR, but even in the case where there are five, seven, etc., receiving portions AR, the depth of the receiving portion AR may be smaller as the receiving portion AR is disposed closer to one end of the first rib RB1 in the longitudinal direction than to a central portion of the first rib RB1.

Additionally, in an embodiment, the bottom surface of each receiving portion AR may be flat. In an alternative embodiment, in another embodiment, the bottom surface of each receiving portion AR may be concave, that is, concave in a direction toward the first surface of the first rib RB1. In other words, each receiving portion AR may be most concave at the center thereof in the longitudinal direction of the receiving portion AR. Accordingly, similar to the above, uniform flatness may be provided within each receiving portion AR.

Although the above description focuses on the first rib RB1, it will be understood that the second rib RB2 may also have the same configuration as described above.

FIG. 6 is a bottom view showing an embodiment of the bottom surface of a mask frame. Because the mask frame in the illustrated embodiment is similar to the mask frame described above, the description below will focus on the differences.

Referring to FIG. 6, in an embodiment, the widths of the plurality of receiving portions AR disposed on the first rib RB1 may be different from each other. In an embodiment, a width w1 of a first receiving portion AR1 disposed in the center from among the plurality of receiving portions AR may be greater than widths w2 and w3 of second and third receiving portions AR2 and AR3 respectively arranged at opposite ends of the first receiving portion AR1, for example. In this case, the first receiving portion AR1 may accommodate more gas than the second receiving portion AR2 and the third receiving portion AR3, and the lifting force applied to the first receiving portion AR1 may be greater than the lifting force applied to the second receiving portion AR2 and the third receiving portion AR3. This may compensate for the phenomenon of further lifting occurring at opposite ends of the first rib RB1. That is, the first receiving portion AR1 disposed in the center of the first rib RB1, which is lifted relatively little by gas injection, may accommodate a relatively large amount of gas and increase the lifting force. Accordingly, uniform flatness may be provided throughout the entirety of the length of the first rib RB1. In addition, the above description focuses on the case where there are three receiving portions AR. However, even in the case where there are five, seven, etc., receiving portions AR, the width of the receiving portion AR may be smaller as the receiving portion AR is disposed closer to one end of the first rib RB1 in the longitudinal direction than to a central portion of the first rib RB1.

In addition, in an embodiment, the depths of the plurality of receiving portions AR may be equal to each other. In an embodiment, the depths of the first receiving portion AR1, the second receiving portion AR2, and the third receiving portion AR3 may be equal to each other, for example.

However, in other embodiments, the depths of the plurality of receiving portions AR may be different from each other. In an embodiment, as described above, the depth of the first receiving portion AR1 disposed in the center of the first rib RB1 may be greater than the depths of the second receiving portion AR2 and the third receiving portion AR2 respectively arranged at opposite ends of the first receiving portion AR1, for example.

Also, in this case, in the second rib RB2, as in the first rib RB1, the widths of the plurality of receiving portions AR may be different from each other. However, in another embodiment, because the second rib RB2 corresponds to the short side, the difference in the degree of flotation in the longitudinal direction due to gas injection may not be large, and accordingly, the widths of the plurality of receiving portions AR may be equal to each other.

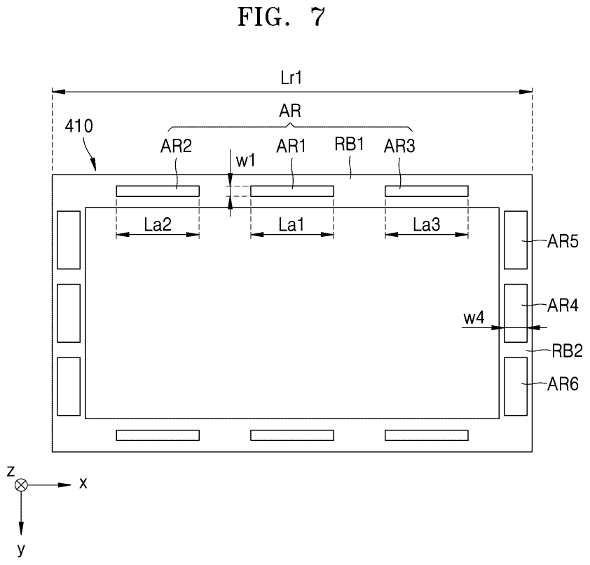

FIG. 7 is a bottom view showing an embodiment of the bottom surface of a mask frame. Because the mask frame in the illustrated embodiment is similar to the mask frame described above, the description below will focus on the differences.

In an embodiment, the widths of a plurality of receiving portions AR disposed on the first rib RB1 may be less than the widths of a plurality of receiving portions AR disposed on the second rib RB2. Specifically, the receiving portions AR disposed on the first rib RB1 may be defined as a first receiving portion AR1, a second receiving portion AR2, and a third receiving portion AR3. The receiving portions AR disposed on the second rib RB2 may be defined as a fourth receiving portion AR4, a fifth receiving portion AR5, and a sixth receiving portion AR6. In this case, a width w1 of the first receiving portion AR1 may be less than a width w4 of the fourth receiving portion AR4. The second rib RB2, which corresponds to a short side, may be lifted less when gas is sprayed than the first rib RB1, which corresponds to a long side. Therefore, by forming the width w4 of the fourth receiving portion AR4 disposed on the second rib RB2 corresponding to the short side to be greater than the width w1 of the first receiving portion AR1 disposed on the first rib RB1 corresponding to the long side, the fourth receiving portion AR4 may accommodate more gas than the first receiving portion AR1 and may provide greater lifting force. This may reduce the difference in the degree of flotation between the first rib RB1 and the second rib RB2. That is, uniform flatness may be provided throughout the mask frame 410.

Although not shown in the drawings, in an embodiment, the depths of the plurality of receiving portions AR disposed on the first rib RB1 may be less than the depths of the plurality of receiving portions AR disposed on the second rib RB2. In this case, the depth of the first receiving portion AR1 may be less than the depth of the fourth receiving portion AR4. The second rib RB2, which corresponds to a short side, may be lifted less when gas is sprayed than the first rib RB1, which corresponds to a long side. Therefore, by forming the depth of the fourth receiving portion AR4 disposed on the second rib RB2 corresponding to the short side to be greater than the depth of the first receiving portion AR1 disposed on the first rib RB1 corresponding to the long side, the fourth receiving portion AR4 may accommodate more gas than the first receiving portion AR1 and may provide greater lifting force. This may reduce the difference in the degree of flotation between the first rib RB1 and the second rib RB2. That is, uniform flatness may be provided throughout the mask frame 410.

In this case, the widths of the plurality of receiving portions AR disposed on the first rib RB1 and the widths of the plurality of receiving portions AR disposed on the second rib RB2 may be different from each other as shown in FIG. 7. However, the disclosure is not limited thereto and the widths of the plurality of receiving portions AR disposed on the first rib RB1 and the widths of the plurality of receiving portions AR disposed on the second rib RB2 may be equal to each other as shown in FIG. 3.

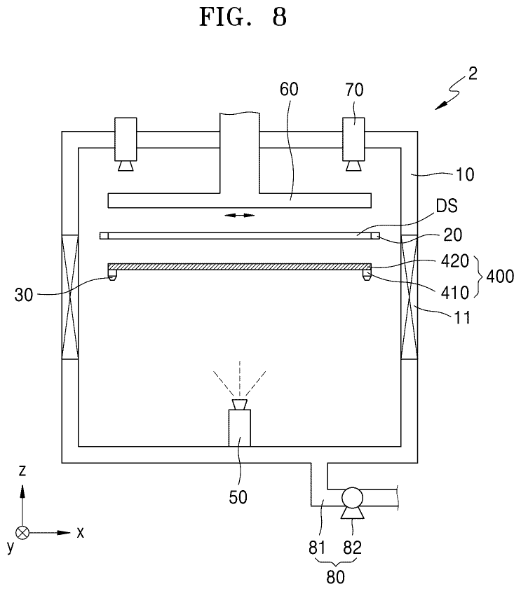

FIG. 8 is a schematic cross-sectional view of an embodiment of an apparatus for manufacturing a display apparatus including a mask frame.

An apparatus 2 for manufacturing a display apparatus may include a chamber 10, a first support portion 20, a second support portion 30, a mask assembly 400, a deposition source 50, a magnetic force portion 60, a vision portion 70, and a pressure control portion 80.

A space in which a display substrate DS and the mask assembly 400 may be accommodated may be defined in the chamber 10. In this case, a portion of the chamber 10 may be open, and a gate valve 11 may be provided in the open portion of the chamber 10. In this case, the open portion of the chamber 10 may be open or closed depending on the operation of the gate valve 11.

In this case, the display substrate DS may mean a display substrate DS in a process of manufacturing a display apparatus, in which at least one of an organic layer, an inorganic layer, or a metal layer is deposited on a substrate 100 to be described below. In an alternative embodiment, the display substrate DS may be the substrate 100 on which none of the organic layer, the inorganic layer, and the metal layer are deposited.

The first support portion 20 may support the display substrate DS. In this case, the first support portion 20 may have a shape of a plate fixed in the chamber 10. In another embodiment, the first support portion 20 is where the display substrate DS is placed, and may be provided in the form of a shuttle capable of linear motion inside the chamber 10. In another embodiment, the first support portion 20 may include an electrostatic chuck or an adhesive chuck that is fixed to the chamber 10 or disposed in the chamber 10 to be movable in the chamber 10.

The second support portion 30 may support the mask assembly 400. In this case, the second support portion 30 may be disposed in the chamber 10. The second support portion 30 may be capable of fine adjustment of the position of the mask assembly 400. In this case, the second support portion 30 may include a separate driving portion, an alignment unit, or the like to move the mask assembly 400 in different directions.

In another embodiment, the second support portion 30 may be provided in the form of a shuttle. In this case, the second support portion 30 is where the mask assembly 400 is placed, and may transfer the mask assembly 400. In an embodiment, the second support portion 30 may move to the outside of the chamber 10 and may enter the chamber 10 from the outside after the mask assembly 400 is placed thereon, for example.

In the above case, the first support portion 20 and the second support portion 30 may be unitary. In this case, the first support portion 20 and the second support portion 30 may each include a movable shuttle. In this case, the first support portion 20 and the second support portion 30 may include structures to fix the mask assembly 400 and the display substrate DS, the display substrate DS being placed on the mask assembly 400, and are capable of linearly moving the display substrate DS and the mask assembly 400 at the same time.

However, in the following description, for convenience of explanation, a case in which the first support portion 20 and the second support portion 30 are separately formed at different positions in the chamber 10 is mainly described in detail.

The deposition source 50 may be disposed to face the mask assembly 400. In this case, the deposition source 50 may include a deposition material, and by applying heat to the deposition material, the deposition material may evaporate or sublimate. The deposition source 50 may be fixed in the chamber 10 or to be capable of linear motion in one direction in the chamber 10.

The mask assembly 400 may be disposed in the chamber 10. In this case, the mask assembly 400 may include a mask frame 410 and a mask sheet 420. The deposition material may be deposited on the display substrate DS by passing through the mask assembly 400.

The magnetic force portion 60 may be disposed in the chamber 10 to face the display substrate DS and/or the mask assembly 400. In this case, the magnetic force portion 60 may apply a force to the mask assembly 400 toward the display substrate DS by applying a magnetic force to the mask assembly 400. In particular, the magnetic force portion 60 may not only prevent sagging of the mask sheet 420, but also make the mask sheet 420 be adjacent to the display substrate DS. Furthermore, the magnetic force portion 60 may maintain a uniform distance between the mask sheet 420 and the display substrate DS.

The vision portion 70 is disposed in the chamber 10, and may capture images of the positions of the display substrate DS and the mask assembly 400. In this case, the vision portion 70 may include a camera for capturing images of the display substrate DS and the mask assembly 400. The positions of the display substrate DS and the mask assembly 400 may be identified based on the images captured by the vision portion 70, and thus, deformation of the mask assembly 400 may be checked. Furthermore, based on the images, the first support portion 20 may finely adjust the position of the display substrate DS or the second support portion 30 may finely adjust the position of the mask assembly 400. However, in the following description, a case in which the positions of the display substrate DS and the mask assembly 400 are aligned with each other by finely adjusting the position of the mask assembly 400 by the second support portion 30 is mainly described in detail.

The pressure control portion 80 is connected to the chamber 10 and may control the pressure in the chamber 10. In an embodiment, the pressure control portion 80 may control the pressure in the chamber 10 to be the same as or similar to atmospheric pressure, for example. Furthermore, the pressure control portion 80 may control the pressure in the chamber 10 to be the same as or similar to a vacuum state.

The pressure control portion 80 may include a connection pipe 81 extended to the chamber 10 and a pump 82 provided on the connection pipe 81. In this case, depending on the operation of the pump 82, external air may be introduced into the chamber 10 through the connection pipe 81 or the gas inside the chamber 10 may be guided to the outside through the connection pipe 81.

In a method of manufacturing a display apparatus (not shown) by the apparatus 2 for manufacturing a display apparatus described above, first, the display substrate DS may be prepared.

The pressure control portion 80 may maintain the inside of the chamber 10 to be the same as or similar to atmospheric pressure, and as the gate valve 11 is operated, the open portion of the chamber 10 may be open.

Then, the display substrate DS may be loaded from the outside of the chamber 10 into the inside thereof. In this case, the display substrate DS may be loaded into the chamber 10 by various methods. In an embodiment, the display substrate DS may be loaded from the outside of the chamber 10 into the inside of the chamber 10 by a robot arm or the like disposed outside the chamber 10, for example. In another embodiment, when the first support portion 20 is formed in the form of a shuttle, it is possible that the first support portion 20 is carried out from the inside of the chamber 10 to the outside of the chamber 10, the display substrate DS is placed on the first support portion 20 by another robot arm or the like disposed outside the chamber 10, and the first support portion 20 is loaded from the outside of the chamber 10 into the chamber 10.

The mask assembly 400 may be disposed in the chamber 10 as described above. In another embodiment, it is possible that the mask assembly 400 is loaded from the outside of the chamber 10 into the chamber 10 in a manner that is the same as or similar to the display substrate DS.

When the display substrate DS is loaded into the chamber 10, the display substrate DS may be placed on the first support portion 20. In this case, the vision portion 70 may capture images of the positions of the display substrate DS and the mask assembly 400. The positions of the display substrate DS and the mask assembly 400 may be identified based on the images captured by the vision portion 70. In this case, the apparatus 2 for manufacturing a display apparatus includes a separate controller (not shown) to identify the positions of the display substrate DS and the mask assembly 400.

When the identification of the positions of the display substrate DS and the mask assembly 400 is complete, the second support portion 30 may finely adjust the position of the mask assembly 400.

Then, as the deposition source 50 is operated, the deposition material may be supplied toward the mask assembly 400, and the deposition material having passed through a plurality of pattern holes of the mask sheet 420 may be deposited on the display substrate DS. In this case, the deposition source 50 may move parallel to the display substrate DS and the mask assembly 400, or the display substrate DS and the mask assembly 400 may move parallel to the deposition source 50. In other words, the deposition source 50 may move relative to the display substrate DS and the mask assembly 400. In this case, the pump 82 inhales or sucks the gas in the chamber 10 and discharges the gas to the outside so that the pressure in the chamber 10 may be maintained to be the same as or similar to a vacuum state.

As described above, the deposition material supplied from the deposition source 50 passes through the mask assembly 400 to be deposited on the display substrate DS, and thus, at least one of a plurality of layers, e.g., an organic layer, an inorganic layer, and a metal layer, to be stacked on a display apparatus to be described below may be formed.

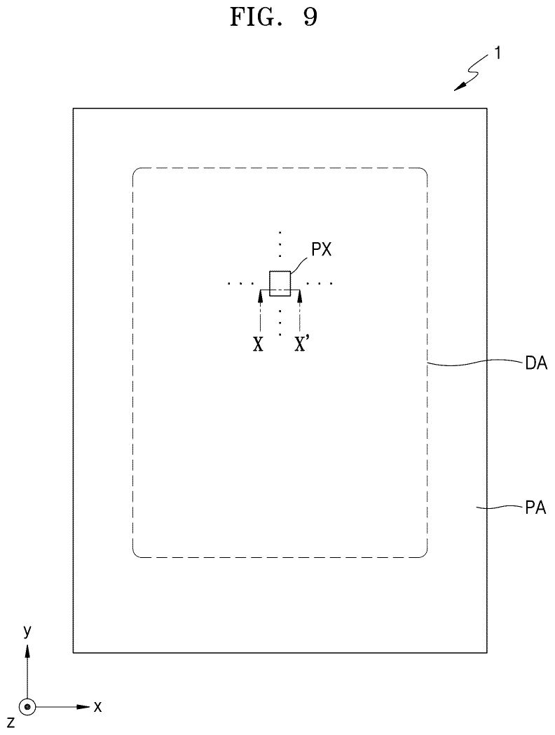

FIG. 9 is a schematic plan view of an embodiment of a display apparatus manufactured by an apparatus for manufacturing a display apparatus.

Referring to FIG. 9, a display apparatus 1 manufactured in an embodiment may include a display area DA and a peripheral area PA disposed outside the display area DA. The display apparatus 1 may provide an image through an array of a plurality of pixels PX two-dimensionally arranged in the display area DA.

The peripheral area PA is an area that does not provide an image, and may surround an entirety of the display area DA or a partial portion of the display area DA. Drivers or the like for providing electrical signals or power to a pixel circuit corresponding to each of the pixels PX may be located in the peripheral area PA. A pad that is an area to which electronic devices, printed circuit boards, or the like may be electrically connected may be disposed in the peripheral area PA.

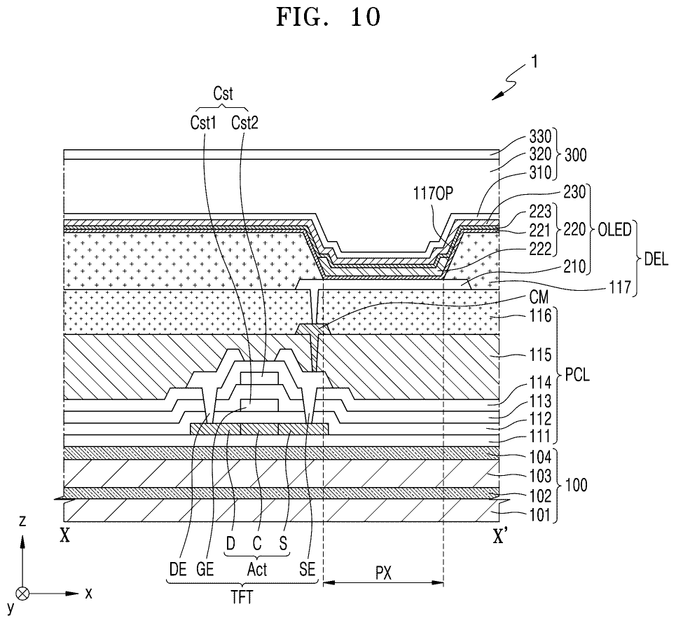

In the following description, although the display apparatus 1 is described as including an organic light-emitting diode OLED (refer to FIG. 10) as a light-emitting element, the disclosure is not limited thereto. In another embodiment, the display apparatus 1 may include a light-emitting display including an inorganic light-emitting diode, that is, an inorganic light-emitting display. The inorganic light-emitting diode may include a PN diode including materials based on an inorganic material semiconductor. When a voltage is supplied to a PN junction diode in a forward direction, holes and electrons are injected, and energy generated due to recombination of the holes and the electrons is converted to light energy so that light of a predetermined color may be emitted. The inorganic light-emitting diode described above may have a width of tens to hundreds of micrometers, and in some embodiments, the inorganic light-emitting diode may be also referred to as a micro LED. In another embodiment, the display apparatus 1 may include a quantum-dot light-emitting display.

The display apparatus 1 may be used as a display screen of various products, e.g., not only portable electronic apparatuses, such as mobile phones, smartphones, tablet personal computers (“PCs”), mobile communication terminals, electronic organizers, electronic books, portable multimedia players (“PMPs”), navigation devices, ultra mobile PCs (“UMPCs”), or the like, but also televisions, notebook computers, monitors, billboards, Internet of things (“IoT”) devices, or the like. Furthermore, the display apparatus 1 in an embodiment may be used in wearable devices, such as smart watches, watch phones, glasses-type displays, head mounted displays (“HMDs”), or the like. Furthermore, the display apparatus 1 in an embodiment may be used as a display for an instrument panel for vehicles, a center information display (“CID”) disposed on the center fascia or dashboard of vehicles, a room mirror display in lieu of a side-view mirror of vehicles, or a display disposed at the rear side of a front seat as an entertainment for a rear seat of vehicles.

FIG. 10 is a schematic cross-sectional view of a display apparatus manufactured by an apparatus for manufacturing a display apparatus, in an embodiment, which may correspond to a cross-section of the display apparatus of FIG. 9 taken along line X-X′ of FIG. 9.

Referring to FIG. 10, the display apparatus 1 may include a stack structure of the substrate 100, a pixel circuit layer PCL, a display element layer DEL, and an encapsulation layer 300. The display substrate DS (refer to FIG. 8) may be obtained by stacking at least one of the pixel circuit layer PCL, the display element layer DEL, and the encapsulation layer 300 on, e.g., the substrate 100 that is in the process of manufacturing the display apparatus 1.

The substrate 100 may have a multilayer structure including a base layer including polymer resin and an inorganic layer. In an embodiment, the substrate 100 may include a base layer including polymer resin and a barrier layer that is an inorganic insulating layer, for example. In an embodiment, the substrate 100 may include a first base layer 101, a first barrier layer 102, a second base layer 103, and a second barrier layer 104, which are sequentially stacked, for example. The first base layer 101 and the second base layer 103 may include polyimide (“PI”), polyethersulfone (“PES”), polyarylate, polyetherimide (“PEI”), polyethylene naphthalate (“PEN”), polyethylene terephthalate (“PET”), polyphenylene sulfide (“PPS”), polycarbonate (“PC”), cellulose triacetate (“TAC”), cellulose acetate propionate (“CAP”), or/or the like. The first barrier layer 102 and the second barrier layer 104 may include an inorganic insulating material, such as a silicon oxide, a silicon oxynitride, and/or a silicon nitride. The substrate 100 may have flexibility.

The pixel circuit layer PCL is disposed on the substrate 100. FIG. 10 illustrates that the pixel circuit layer PCL includes a thin-film transistor TFT, and a buffer layer 111, a first gate insulating layer 112, a second gate insulating layer 113, an inter-insulating layer 114, a first planarization insulating layer 115, and a second planarization insulating layer 116, which are disposed below or/and above constituent elements of the thin-film transistor TFT.

The buffer layer 111 may reduce or block infiltration of foreign materials, such as moisture or external air, from under the substrate 100, and may provide a planarized surface on the substrate 100. The buffer layer 111 may include an inorganic insulating material, such as a silicon oxide, a silicon oxynitride, and a silicon nitride, and may have a single layer or multilayer structure including the above-described materials.

The thin-film transistor TFT on the buffer layer 111 may include a semiconductor layer Act, and the semiconductor layer Act may include polysilicon. In an alternative embodiment, the semiconductor layer Act may include amorphous silicon, an oxide semiconductor, an organic semiconductor, or the like. The semiconductor layer Act may include a channel region C and a drain region D and a source region S located at opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), titanium (Ti), or the like, and may be a multilayer or single layer including the above materials.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. ZnOₓ may include ZnO and/or ZnO₂.

The second gate insulating layer 113 may cover the gate electrode GE. The second gate insulating layer 113, similar to the first gate insulating layer 112, may include an inorganic insulating material, such as SiO₂, SiNₓ, SiON, Al₂O₃, TiO₂, Ta₂O₅, HfO₂, or ZnOₓ. ZnOₓ may include ZnO and/or ZnO₂.

An upper electrode Cst2 of a storage capacitor Cst may be disposed on the second gate insulating layer 113. The upper electrode Cst2 may overlap the gate electrode GE thereunder. In this case, the gate electrode GE and the upper electrode Cst2 overlapping each other with the second gate insulating layer 113 therebetween may form the storage capacitor Cst. In other words, the gate electrode GE may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be a single layer or multilayer including the above-described materials.

The inter-insulating layer 114 may cover the upper electrode Cst2. The inter-insulating layer 114 may include SiO₂, SiNₓ, SiON, Al₂O₃, TiO₂, Ta₂O₅, HfO₂, ZnOₓ, or the like. ZnOₓ may include ZnO and/or ZnO₂. The inter-insulating layer 114 may be a single layer or multilayer including the above-described inorganic insulating material.

A drain electrode DE and a source electrode SE may each be disposed on the inter-insulating layer 114. The drain electrode DE and the source electrode SE may be respectively connected to the drain region D and the source region S through contact holes defined in the insulating layers thereunder. The drain electrode DE and the source electrode SE may include a material exhibiting excellent conductivity. The drain electrode DE and the source electrode SE may include a conductive material including Mo, Al, Cu, Ti, or the like, and may be a multilayer or single layer including the above material. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material, such as general purpose polymers such as polymethylmethacrylate (“PMMA”) or polystyrene (“PS”), polymer derivatives having a phenolic group, acrylic polymers, imide-based polymers, aryl ether-based polymers, amide-based polymers, fluorine-based polymers, p-xylene-based polymers, vinyl alcohol-based polymers, or any combinations thereof.

The second planarization insulating layer 116 may be disposed on the first planarization insulating layer 115. The second planarization insulating layer 116 may include the same material as that of the first planarization insulating layer 115, and may include an organic insulating material, such as general purpose polymers such as PMMA or PS, polymer derivatives having a phenolic group, acrylic polymers, imide-based polymers, aryl ether-based polymers, amide-based polymers, fluorine-based polymers, p-xylene-based polymers, vinyl alcohol-based polymers, or any combinations thereof.

The display element layer DEL may be disposed on the pixel circuit layer PCL having the above-described structure. The display element layer DEL may include an organic light-emitting diode OLED as a display element (that is, a light-emitting element), and the organic light-emitting diode OLED may include a stack structure of a pixel electrode 210, an intermediate layer 220, and a common electrode 230. The organic light-emitting diode OLED may emit, e.g., red, green, or blue light, or red, green, blue, or white light. The organic light-emitting diode OLED may emit light through a light-emitting area, and the light-emitting area may be defined to be a pixel PX.

The pixel electrode 210 of the organic light-emitting diode OLED may be electrically connected to the thin-film transistor TFT through contact holes defined in the second planarization insulating layer 116 and the first planarization insulating layer 115 and a contact metal CM disposed on the first planarization insulating layer 115.

The pixel electrode 210 may include a conductive oxide, such as an indium tin oxide (“ITO”), an indium zinc oxide (“IZO”), ZnO, an indium oxide (In₂O₃), an indium gallium oxide (“IGO”), or an aluminum zinc oxide (“AZO”). In another embodiment, the pixel electrode 210 may include a reflective film including Ag, Mg, Al, Pt, Pd, Au, Ni, Nd, Ir, Cr, or any combinations thereof. In another embodiment, the pixel electrode 210 may further include a layer including ITO, IZO, ZnO, or In₂O₃ above/below the above-described reflective film.

A pixel-defining layer 117 defining an opening 117OP that exposes a center portion of the pixel electrode 210 is disposed on the pixel electrode 210. The pixel-defining layer 117 may include an organic insulating material and/or an inorganic insulating material. The opening 117OP may define a light-emitting area where light from the organic light-emitting diode OLED is emitted. In an embodiment, the size/width of the opening 117OP may correspond to the size/width of the light-emitting area, for example. Accordingly, the size and/or width of the pixel PX may depend on the size and/or width of the opening 117OP of the pixel-defining layer 117 corresponding to the pixel PX.

The intermediate layer 220 may include an emission layer 222 formed to correspond to the pixel electrode 210. The emission layer 222 may include a polymer or low molecular weight organic material that emits light of a predetermined color. In an alternative embodiment, the emission layer 222 may include an inorganic light-emitting material or quantum dots.

In an embodiment, the intermediate layer 220 may include a first functional layer 221 and a second functional layer 223 which are respectively disposed below and above the emission layer 222. The first functional layer 221 may include, e.g., a hole transport layer (“HTL”), or HTL and a hole injection layer (“HIL”). The second functional layer 223 that is disposed above the emission layer 222 may include an electron transport layer (“ETL”) and/or an electron injection layer (“EIL”). The first functional layer 221 and/or the second functional layer 223, like the common electrode 230 described below, may be a common layer that covers an entirety of the substrate 100.

The common electrode 230 is disposed on the pixel electrode 210, and may overlap the pixel electrode 210. The common electrode 230 may include a conductive material having a relatively low work function. In an embodiment, the common electrode 230 may include a (semi-) transparent layer including Ag, Mg, Al, Pt, Pd, Au, Ni, Nd, Ir, Cr, lithium (Li), Ca, any alloys thereof, or the like, for example. In an alternative embodiment, the common electrode 230 may further include a layer including ITO, IZO, ZnO or In₂O₃ on the (semi-)transparent layer including the above-described materials. The common electrode 230 may be unitary to cover an entirety of the substrate 100.

The encapsulation layer 300 may be disposed on the display element layer DEL and may cover the display element layer DEL. The encapsulation layer 300 includes at least one an inorganic encapsulation layer and at least one organic encapsulation layer, and in an embodiment, FIG. 10 illustrates that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials among an aluminum oxide, a titanium oxide, a tantalum oxide, a hafnium oxide, a zinc oxide, a silicon oxide, a silicon nitride, and a silicon oxynitride. The organic encapsulation layer 320 may include a polymer-based material. The polymer-based material may include acrylic resin, epoxy-based resin, polyimide, polyethylene, or the like. In an embodiment, the organic encapsulation layer 320 may include acrylate. The organic encapsulation layer 320 may be formed by curing a monomer or applying a polymer. The organic encapsulation layer 320 may have transparency.

Although not shown, a touch sensor layer may be disposed on the encapsulation layer 300, and an optical functional layer may be disposed on touch sensor layer. The touch sensor layer may obtain coordinates information according to an external input, e.g., a touch event. The optical functional layer may reduce reflectivity of light (external light) incident on a display apparatus from the outside, and/or may improve the color purity of light emitted from the display apparatus. In an embodiment, the optical functional layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and a liquid crystal coating type may include liquid crystals disposed in a predetermined array. The retarder and the polarizer may further include a protective film.

An adhesive member may be disposed between the touch electrode layer and the optical functional layer. The adhesive member may employ any general member that is well-known in the field of technology without limitation. The adhesive member may be a pressure sensitive adhesive (“PSA”).

By embodiments, the flatness of the mask frame may be improved and the mask sheet may be disposed at an exact position of the mask frame.

The effects of the disclosure are not limited to the effects mentioned above, and other effects not mentioned will be clearly understood by those of ordinary skill in the art from the description of the claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A mask assembly comprising:
a mask frame including:
a plurality of ribs including a first rib extending in a first direction, the plurality of ribs defining an opening area; and
a plurality of receiving portions disposed on a first surface of the first rib and spaced apart from each other in a longitudinal direction of the first rib; and
a mask sheet disposed on a second surface of the first rib of the mask frame and covering the opening area, the second surface being opposite to the first surface.

2. The mask assembly of claim 1, wherein the plurality of receiving portions is provided in an odd number.

3. The mask assembly of claim 1, wherein each of the plurality of receiving portions has a constant width in the longitudinal direction.

4. The mask assembly of claim 1, wherein the plurality of receiving portions includes a first receiving portion disposed at a center of the first rib and a second receiving portion disposed at at least one of opposite ends of the first receiving portion in the longitudinal direction, and
wherein a width of the first receiving portion is greater than a width of the second receiving portion.

5. The mask assembly of claim 1, wherein the plurality of receiving portions includes a first receiving portion disposed at a center of the first rib and a second receiving portion disposed at at least one of opposite ends of the first receiving portion in the longitudinal direction, and
wherein a depth of the first receiving portion is greater than a depth of the second receiving portion.

6. The mask assembly of claim 1, wherein the plurality of ribs includes a second rib extending in a second direction crossing the first direction and having a shorter length than a length of the first rib, and
wherein a depth of a receiving portion, among the plurality of receiving portions, disposed on the second rib is greater than a depth of a receiving portion, the plurality of receiving portions, disposed on the first rib.

7. The mask assembly of claim 6, wherein a width of the receiving portion disposed on the second rib is greater than a width of the receiving portion disposed on the first rib.

8. The mask assembly of claim 1, wherein a ratio of a sum of lengths of the plurality of receiving portions to a length of the first rib is about 0.8 to about 0.9.

9. The mask assembly of claim 1, wherein a bottom surface of each of the plurality of receiving portions is concavely formed toward the second surface of the first rib on which the mask sheet is disposed.

10. The mask assembly of claim 1, wherein a depth of each of the plurality of receiving portions corresponds to about 3% to about 10% of a thickness of the mask frame.

11. A method of manufacturing a mask assembly, the method comprising:
disposing, on a mask stage, a mask frame including a first rib extending in a first direction;
fixing a mask sheet on the mask frame; and
spraying gas into a plurality of receiving portions disposed on one surface of the first rib facing the mask stage and spaced apart from each other in a longitudinal direction of the first rib.

12. The method of claim 11, wherein an odd number of receiving portions is disposed on the first rib.

13. The method of claim 11, wherein each of the plurality of receiving portions has a constant width in the longitudinal direction.

14. The method of claim 11, wherein the plurality of receiving portions includes a first receiving portion disposed at a center of the first rib and a second receiving portion disposed at at least one of opposite ends of the first receiving portion in the longitudinal direction, and
wherein a width of the first receiving portion is greater than a width of the second receiving portion.

15. The method of claim 11, wherein the plurality of receiving portions includes a first receiving portion disposed at a center of the first rib and a second receiving portion disposed at at least one of opposite ends of the first receiving portion in the longitudinal direction, and
wherein a depth of the first receiving portion is greater than a depth of the second receiving portion.

16. The method of claim 11, wherein the mask frame further includes a second rib extending in a second direction crossing the first direction and having a shorter length than a length of the first rib, and
wherein a depth of a receiving portion, among the plurality of receiving portions, disposed on the second rib is greater than a depth of a receiving portion, among the plurality of receiving portions, disposed on the first rib.

17. The method of claim 16, wherein a width of the receiving portion disposed on the second rib is greater than a width of the receiving portion disposed on the first rib.

18. The method of claim 11, wherein a ratio of a sum of lengths of the plurality of receiving portions to a length of the first rib is about 0.8 to about 0.9.

19. An apparatus for manufacturing a display apparatus, the apparatus comprising:
a chamber;
a deposition source accommodated in the chamber and facing a display substrate; and
a mask assembly disposed between the display substrate and the deposition source, the mask assembly including:
a mask frame including:
a plurality of ribs including a first rib extending in a first direction, the plurality of ribs defining an opening area; and
a plurality of receiving portions disposed on a first surface of the first rib and spaced apart from each other in a longitudinal direction of the first rib; and
a mask sheet disposed on a second surface of the first rib of the mask frame and covering the opening area, the second surface being opposite to the first surface.

20. The apparatus of claim 19, wherein the plurality of receiving portions is provided in an odd number.
